(19) United States
(12) Patent Application Publication
(10) Pub. No.: US 2015/0318403 A1
(43) Pub. Date: Nov. 5, 2015

(54) ALUMINUM SUBSTRATE FOR A THIN FILM TRANSISTOR

(71) Applicant: ALCOA INC., Pittsburgh, PA (US)

(72) Inventors: Thomas L. Levendusky, Greensburg, PA (US); Kirit Shah, Monroeville, PA (US); Marcia Gregory, Lancaster, PA (US); Jeff S. VanBrookhoven, Lititz, PA (US); Miltiadis K. Hatalis, Bethlehem, PA (US)

(21) Appl. No.: 14/700,991

(22) Filed: Apr. 30, 2015

Related U.S. Application Data
(60) Provisional application No. 61/986,640, filed on Apr. 30, 2014.

(51) Int. Cl. H01L 29/786; H01L 29/51; H01L 21/477; H01L 29/66

(52) U.S. Cl. CPC H01L 29/78603; H01L 29/66742; H01L 29/512; H01L 21/477

(57) ABSTRACT

A substrate comprises of a recrystallized aluminum alloy. An organic polymer layer coats the top surface of the aluminum substrate. A layer of one of: SiO₂, SiN and Al₂O₃ is on the organic polymer and at least one electrode is adhered to the layer of one of: SiO₂, SiN and Al₂O₃. A method comprises depositing an organic polymer on an aluminum substrate, annealing the aluminum substrate; depositing a layer of one of SiO₂, SiN and Al₂O₃ on the organic polymer; and adhering an electrode to the layer of one of: SiO₂, SiN and Al₂O₃.

### CROSS-REFERENCE TO RELATED APPLICATIONS

This patent application claims priority to U.S. Provisional Patent Application No. 61/986,640, filed Apr. 30, 2014, which is incorporated herein by reference in its entirety.

### BACKGROUND

A thin-film transistor (TFT) is a special kind of field-effect transistor made by depositing thin films of an active semiconductor layer over a supporting (but non-conducting) substrate. This differs from the conventional transistor, where the semiconductor material typically is the substrate, such as a silicon wafer. These TFT's are fundamental components in modem-age electronics, including, for example, sensors, imaging, and display devices. A common substrate is glass because the primary application of TFT's is in liquid-crystal displays.

### SUMMARY

Referring to FIG. 1, a device comprises a recrystallized aluminum substrate 110, an organic polymer 120 on a top surface of the aluminum substrate 110, a layer of silicon dioxide 130 on the organic polymer 120, and electrodes 140 adhered to the silicon dioxide 130. In some embodiments, a number of other layers are over the electrodes 140 and silicon dioxide 130 to form a thin film transistor 100. In some embodiments, the organic polymer 120 is directly of the top surface of the aluminum substrate 110. In some embodiments, the layer of silicon dioxide 130 is directly on the organic polymer 120.

In some embodiments, the recrystallized aluminum substrate 110 comprises one of 1xxx., 3xxx, 5xxx or 8xxx aluminum alloy. In some embodiments, the recrystallized aluminum substrate 110 has an O Temper. In some embodiments, the recrystallized aluminum substrate 110 has a thickness in the range of 0.005-0.020 inches. In some embodiments, the recrystallized aluminum substrate 110 has a thickness in the range of 0.006-0.020 inches. In some embodiments, the recrystallized aluminum substrate 110 has a thickness in the range of 0.013-0.014 inches.

In some embodiments, the organic polymer 120 comprises one of an epoxy, acrylic, polyester or vinyl. In some embodiments, the organic polymer 120 has a molecular weight in the range of 800 to 2000 Daltons. In some embodiments, the organic polymer 120 has a molecular weight in the range of 1000-2000 Daltons. In some embodiments, the organic polymer 120 is able to be applied to a coil of aluminum via roll-coating. In some embodiments, the organic polymer 120 has a thickness in the range of 2.5-50 microns. In some embodiments, the organic polymer 120 has a thickness in the range of 5-12 microns. In some embodiments, the organic polymer 120 is adhered to the recrystallized aluminum substrate 110.

In some embodiments, instead of silicon dioxide, there is a layer of SiN on the organic polymer 120. In some embodiments, instead of silicon dioxide, there is a layer of Al2O3 on the organic polymer 120. The layer of silicon dioxide, SiN or Al2O3 130 is sufficiently thick so that electrodes 140 adhere to the layer of silicon dioxide, SiN, or Al2O3 130. In some embodiments, the layer of silicon dioxide, SiN or Al2O3 130 has a thickness in the range of 750-1500 angstroms. In some embodiments, the layer of silicon dioxide, SiN or Al2O3 130 has a thickness in the range of 1000-1250 angstroms.

Adhered means there is no lifting of gate dielectric layer or the gate electrode by visual inspection.

In some embodiments, the device comprises a thin film transistor 100.

Referring to FIG. 2, a method comprises depositing an organic polymer on an aluminum substrate 200; annealing the aluminum substrate 210; depositing a layer of silicon dioxide, SiN or Al2O3 on the aluminum substrate 220; and adhering an electrode to the layer of silicon dioxide 230.

Referring to FIG. 3, in some embodiments, annealing 210 comprises heating the aluminum substrate to a temperature in the range of 550 to 650° F. for 2 to 4 hours 300. In some embodiments, during annealing, the aluminum substrate is held at a temperature in the range of 550 to 650° F. for 2 to 4 hours. In sonic embodiments, annealing comprises heating the aluminum substrate to a temperature of 600° F. for 4 hours.

Referring to FIG. 4, in some embodiments, depositing an organic polymer 200 comprises one of reverse roll coating, roll coating, slot die coating, curtain coating, or spray coating 400.

In some embodiments, depositing a layer of silicon dioxide, SiN or Al2O3 comprises radio frequency (“RF”) sputtering. In some embodiments, depositing a layer of silicon dioxide, SiN or Al2O3 comprises RF sputtering at room temperature. Room temperature is in the range of 60° F.-85° F. RF sputtering involves running radio waves through an inert gas to create positive ions. The target material, which will ultimately become the layer being deposited, is struck by these ions and broken up into a fine spray that covers the substrate.

Referring to FIG. 5, in some embodiments, the aluminum substrate is finished 500 so that aluminum substrate has a Ra value in the range of 25 to 100 nm. In some embodiments wherein the substrate is a metal substrate, finishing comprises rolling. In other embodiments finishing comprises chemical brightening.

Rolling means use of machined rolls, oppositely opposed, wherein the metal substrate passes between the nip of the rolls. This reduces the thickness of the metal substrate, and under conditions where the rolls are sufficiently polished, the metal substrate will have a bright surface and a Ra value in the range of 25 to 200 nm.

Chemical brightening means use of acids at elevated temperatures, which selectively etch the metal surface, This etching removes the peaks on the metal surface, in turn yielding a surface with increased specularity.

A method comprises depositing a layer of silicon dioxide on a layer of an organic polymer on a recrystallized aluminum substrate; and adhering an electrode to the layer of silicon dioxide.

A substrate is a supporting material.

An electrode is a conductor through which electricity enters or leaves an object.

Roll coating is the process of applying a coating, to a flat substrate by passing it between rollers. Coating is applied by one auxiliary roller onto an application roil, which rolls across the conveyed flat substrate. There are two types of roll coating: direct and reverse roll coating. In direct roll coating, the applicator roll rotates in the same direction as the substrate moves. In reverse roll coating, the applicator roll rotates in the opposite direction of the substrate. Slot die coating comprises forcing a coating liquid out from a reservoir, through a slot by pressure and onto a substrate moving relative to the slot. Curtain coating comprises passing a horizontally fiat substrate on a conveyor underneath a steady stream of coating material falling onto the substrate. Spray coating comprises coating a substrate with a liquid spray. More information regarding these coating techniques can be found in Modern Coating. and Drying Technology, editors Edward Cohen & Edgar Cutoff, Wiley-VCH, Inc., isbn 1-56081-097-1, 1992, which is incorporated herein by reference.

The alloys mentioned herein are as defined by the Aluminum Association International Alloy Designations and Chemical Composition Limits for Wrought Aluminum and Wrought Aluminum Alloys as revised February 2009.

### DESCRIPTION OF THE FIGURES

FIG. 1 depicts a side cross section view of a TFT according to one embodiment;

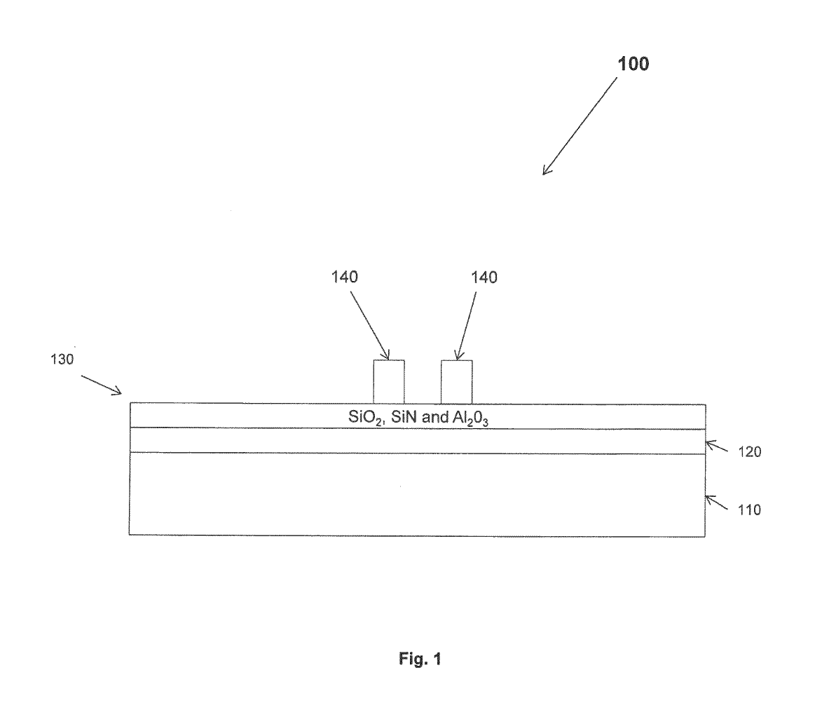

FIG. 2 illustrates a method according to one embodiment;

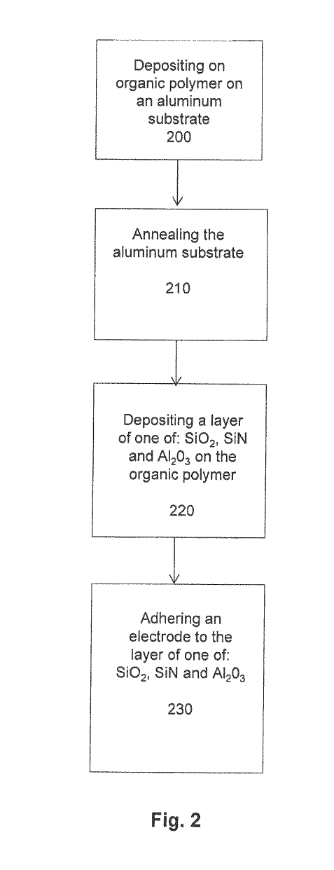

FIG. 3 illustrates a method according to another embodiment;

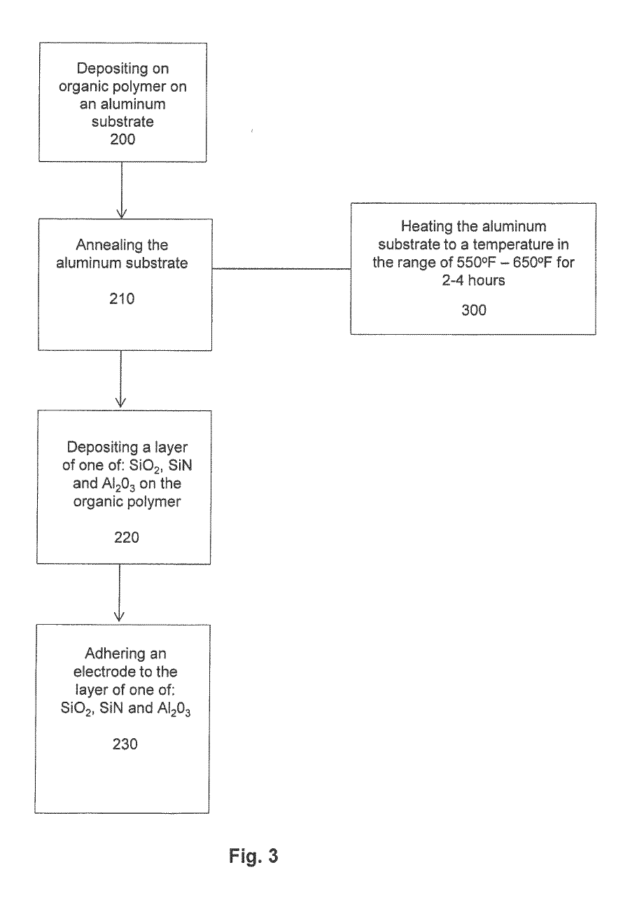

FIG. 4 illustrates a method according to a further embodiment;

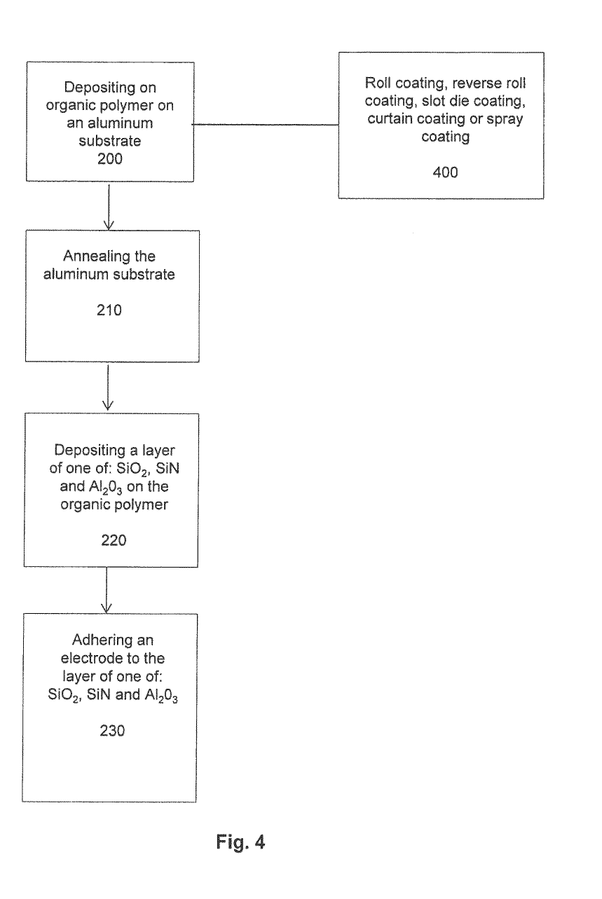

FIG. 5 illustrated a method according to yet a further embodiment;

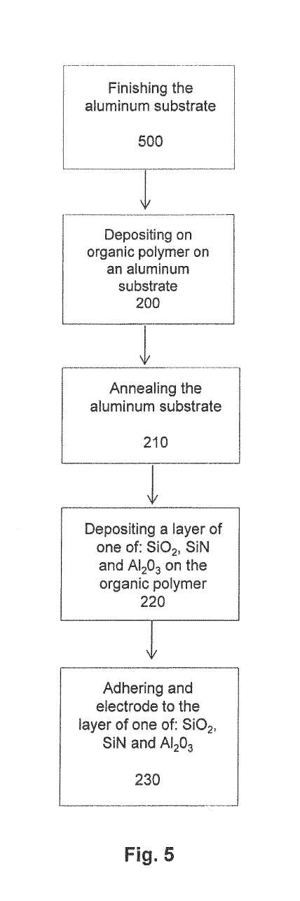

FIG. 6 shows a comparison of grain structure of a substrate before and after annealing;

FIG. 7 illustrates a side cross section view of a TFT;

FIG. 8 is a top view if the layout of the TFT shown in FIG. 7 having a channel area of W40 μm and L26 μm;

FIG. 9 is a graph showing the drain current versus the drain voltage of the TFT in Example 2; and

FIG. 10 is a graph showing the transfer characteristics of the TFT in Example 2.

### DESCRIPTION

### Example 1

Organic polymer layers were deposited on unannealed, H-temper aluminum substrates. These organic polymer layers provide insulating characteristics and planarizing (i.e., smoothness) properties required for TFT fabrication. The aluminum substrates with the organic polymer layers were annealed at elevated temperatures (i.e., 300-325° C.) to achieve the required thermal stability. Typically, organic polymer coatings show poor performance when exposed to temperatures above 260° C. for long periods of time. Heat treating/annealing studies at temperatures from 316-320° C. (600-610° F.) were conducted for three to four hours to investigate the thermal stability of the insulated (i.e., organic polymer coated) aluminum substrate. For those skilled in the art of the properties of organic coatings, it is not obvious to conduct this annealing step due to potential degradation of the organic layer.

Three different variables of aluminum substrates were tested: (Type-1): AA 8006 H25P temper substrate coated both sides with an organic polymer (epoxy polymer) and annealed for hrs at 316-320° C. (after annealing the substrate had a T-temper); (Type-2): AA 8006 H25P temper substrate coated with an organic polymer (epoxy polymer) both sides but not annealed; & (Type-3): AA 5657 H18 temper substrate coated on the front side only with ultraviolet (UV) curable organic polymer (epoxy acrylate polymer) but not annealed.

Several samples from each of the three variables were then RF-sputtered coated with 150 nanometers (nm) of Molybdenum (Mo) and then subjected to the photolithographic process to pattern/etch the Mo-layer in order to form Mo-electrodes. This step was performed successfully confirming that the integrity of the substrates is compatible with photolithographic processing.

After resist stripping, 100 nm thick silicon dioxide (SiO2) film was deposited via plasma enhanced chemical vapor deposition (PECVD) using silane and nitrous oxide as reactant gases. The deposition temperature was 270° C. and the total exposure at process temperature was 50 minutes. After the deposition step, the integrity of the substrates and deposited coatings was evaluated. After the PECVD step, only the Type-1 aluminum substrate did not have any cracks.

The dimensional stability of the Type-1 substrate after the above PECVD step was evaluated by performing a second lithographic processing step which results in a second pattern. Based on the registration error between the two patterns, it was determined that the Type-1 exhibits shrinkage of 3+1 μm across a 150 mm substrate. This result confirms that Type-1 is compatible with IGZO TFTs.

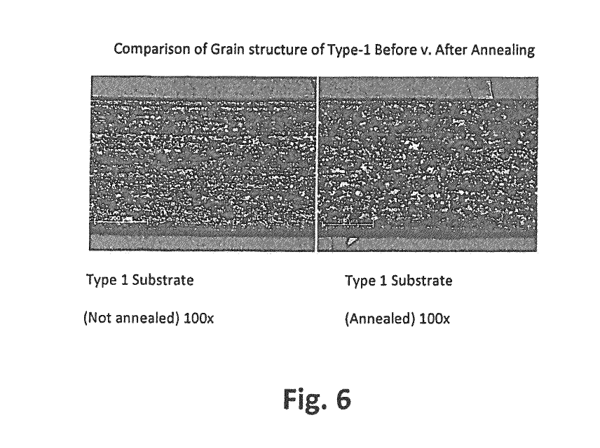

One reason for the increased dimensional stability is the change in the microstructure of the aluminum substrate after the annealing step. Recrystallization is defined as the formation of a new grain structure in a deformed material by the formation and migration of high angle grain boundaries driven by the stored energy of deformation. Strain/work hardened aluminum alloys were investigated in these studies. The annealing step provided the energy to form new grains that resulted in a thermally-stable substrate when exposed to the photolithographic steps. The change in recrystallized grain microstructure is depicted in FIG. 6.

The adhesion of the gate dielectric layer over the gate electrode is important for operation of the TFT. In the investigations described above, the adhesion of the GaN2 (gallium nitride) gate dielectric layer was insufficient, resulting in a non-working TFT device. It was also found that substituting a different gate electrode (aluminum) in combination with same gallium nitride (GaN2) dielectric layer also resulted in adhesion issues. To improve the adhesion, an additional layer of SiO2 was deposited over the planarized annealed Type 1 aluminum substrate. This additional layer of SiO2 resulted in optimum adhesion between the gate dielectric layer and the gate electrode. The reason for this enhanced adhesion is that the additional layer (SiO2) serves to reduce mismatch in the coefficient of thermal expansion (CTE) between the gate electrode and the planarized aluminum substrate. The temperatures utilized during the deposition of the gate dielectric are such that the additional layer (SiO2) mitigates/reduces the tendency for the adhesion loss.

Testing Procedures:
TFT's with different geometries were tested from each substrate.
Device transfer characteristics and gate leakage currents were measured at VDS =0.1 V and ±10 V for a VGS in the range of −10 V to +20 V.
Mobility was extracted from the maximum transconductance and threshold voltage using the linear extrapolation method from the characteristics obtained at VDS=0.1 V.

An automated probe station enabled device characterization over the entire wafer.

### Example 2

An amorphous InGaZnO TFTs was fabricated on Type 1 aluminum substrates from Example 1 above. The aluminum substrate was coated with an organic layer which served to both planarize the aluminum surface and to provide an insulating coating for device fabrication upon it.

The challenge caused by the thermal expansion coefficient mismatch between the coated aluminum substrate and PECVD gate dielectrics deposited at 270° C., which resulted in stress and adhesion problems, was overcome. This problem was solved by RF-sputtering at room temperature a thin SiO2 layer on top of the organic coating of the aluminum substrate before the onset of TFT fabrication.

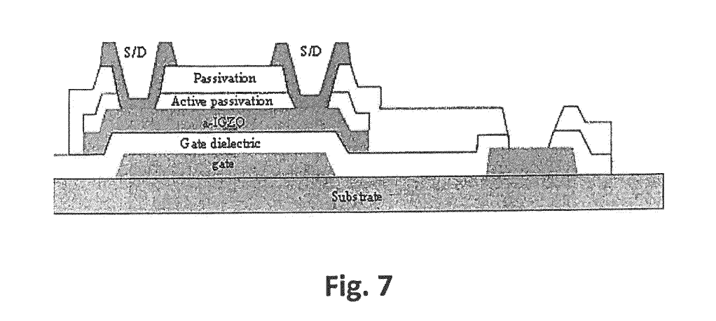

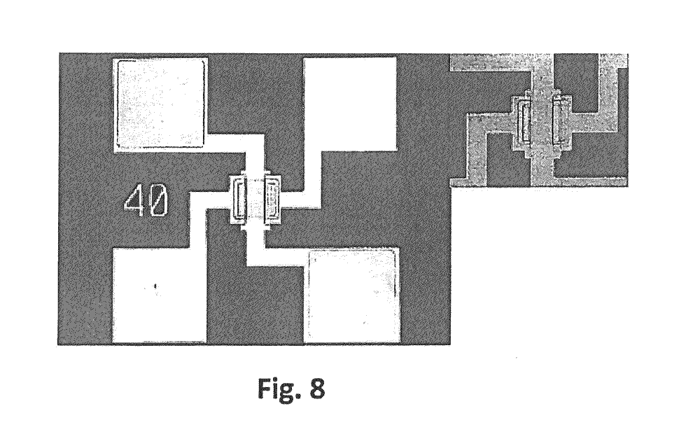

The TFT device structure, illustrated in FIGS. 7 and 8, was a modified etch stop structure with S/D contact windows. First, a 140 nm layer of AlNd formed the gate electrodes. Then a stack of 110 nm SiO2 was deposited by PECVD at 270° C. as the gate dielectric. 40 nm a-IGZO and 50 nm SiO2 layers were then deposited by RF magnetron to form channel and first passivation layers, respectively. Next, SiO2 was dry etched by RIE system and IGZO layer was patterned by diluted HCL. After active etch, a second passivation layer of SiO2 with 50 nm thickness was deposited. Then, gate pads and source/drain contact windows were deposited via dry etching. Finally, source and drain electrodes were formed by patterning a double layer of 70 nm Mo and 100 nm AlNd by lift off process. The wafer was then annealed in N2 ambient at 300° C. for a total of two hours.

Mobility was extracted from the maximum transconductance at VDS=0.1 V. TFTs with a 26 μm channel length and 40 μm channel width displayed an average field effect mobility of 8.6 cm2 V-1s-1 (maximum of 13.3), threshold voltage of about 5 V, minimum off current less than 1 pA, and an on-off current ratio of more than 107 at Vds=+10 V (maximum of more than 108). Prior to the final thermal annealing, the TFTs exhibited no modulation and a high current due to the high conductivity of the IGZO Film.

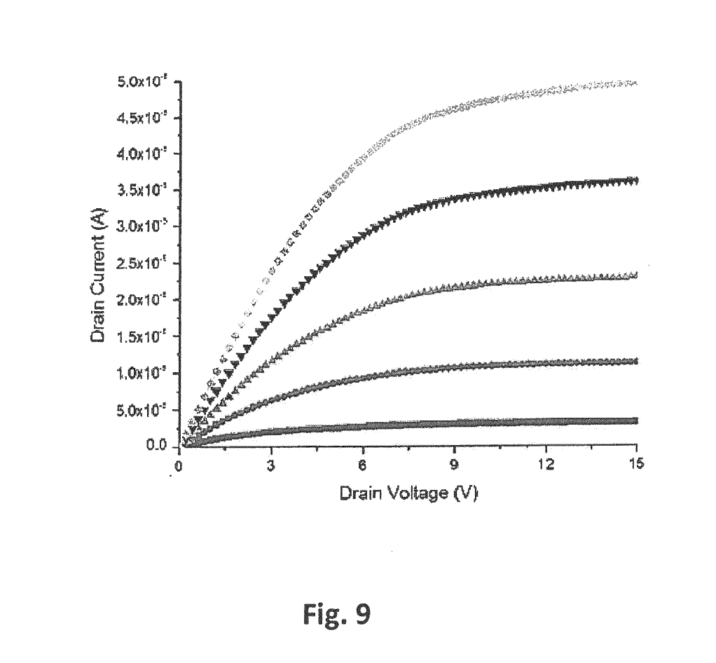

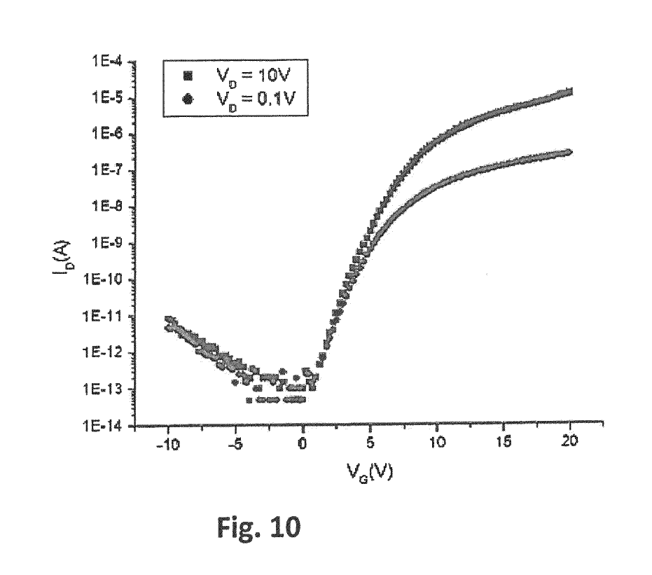

FIG. 9 shows the output characteristics of the a transistor on the TFT in Example 2 with length 14 μm and width 32 μm for Vg increment from 10 to 25 V. FIG. 10 shows the transfer characteristics of a transistor of on the TFT in Example 2 of length 5 μm and width 20 μm (right).

While various embodiments of the present disclosure have been described in detail, it is apparent that modifications and adaptations of those embodiments will occur to those skilled in the art. However, it is to be expressly understood that such modifications and adaptations are within the spirit and scope of the present disclosure.

1. A device comprising:
a. a substrate comprised of a recrystallized aluminum alloy;
b. an organic polymer on top surface of the aluminum substrate;
C. a layer of one of: SiO2, SIN and Al2O3 on the organic polymer; and
d. at least one electrode adhered to the layer of one of SiO2, SiN and Al2O3.

2. The device of claim 1 wherein the substrate comprises on of AA 1xxx, 3xxx, 5xxx and 8xxx.

3. The device of claim 1 wherein the recrystalized aluminum alloy has an O temper.

4. The device of claim 1 wherein the organic polymer has a molecular weight in the range of 800 to 2000 Daltons.

5. The device of claim 1 wherein the organic polymer has a molecular weight in the range of 1000 to 2000 Daltons.

6. The device of claim 1 wherein the organic polymer comprises one of: epoxy, acrylic, polyester, and vinyl.

7. The device of claim 1 wherein the substrate has a thickness in the range of 0.005 inches 0.020 inches.

8. The device of claim 1 wherein the substrate has a thickness in the range of 0.006 inches-0.020 inches.

9. The device of claim 1 wherein the organic polymer has a thickness in the range of 2.5-50 microns.

10. The device of claim 1 wherein the organic polymer has a thickness in the range of 5-12 microns.

11. The device of claim 1 wherein the layer of one of: SiO2, SIN and Al2O3 has a thickness in the range of 750-1500 angstroms.

12. The device of claim 1 wherein the layer of one of: SiO2, SiN and Al2O3 has a thickness in the range of 1000-1250 angstroms.

13. The device of claim 1 wherein the device comprises a thin film transistor.

14. A method comprising:
a. depositing an organic polymer on an aluminum substrate;
b. annealing the aluminum substrate;
c. depositing a layer of one of: SiO₂, SiN and Al₂O₃ on the organic polymer; and
d. adhering an electrode to the layer of one of: SiO₂, SiN and Al₂O₃.

15. The method of claim 17 wherein the aluminum substrate comprises:
a. a top surface; and
b. pores on the top surface.

16. The method of claim 17 wherein the aluminum substrate has an H temper before annealing and an O Temper after annealing.

17. The method of claim 17 wherein annealing comprises heating the aluminum substrate to a temperature in the range of 550° F.-650° F. for 2 hrs to 4 hours.

18. The method of claim 17 wherein depositing an organic polymer comprises on of: roll coating; reverse roll coating; slot die coating; curtain coating; and spray coating.

19. The method of claim 17 wherein depositing the layer of one of: SiO2, SiN and Al2O3 comprises RF-sputtering.

20. The method of claim 17 further comprising finishing the aluminum substrate to have a Ra value in the range of 25 to 100 nm, before step a, depositing an organic polymer on an aluminum substrate.
